(19) United States
(12) Patent Application Publication
(10) Pub. No.: US 2017/0229295 A1
(43) Pub. Date: Aug. 10, 2017

(54) SPUTTERING DEVICE COMPONENT WITH MODIFIED SURFACE AND METHOD OF MAKING

(71) Applicant: Honeywell International Inc., Morris Plains, NJ (US)

(72) Inventors: Jaeyeon Kim, Liberty Lake, WA (US); Patrick K. Underwood, Spokane, WA (US); Susan D. Strothers, Mead, WA (US); Michael D. Payton, Rockford, WA (US); Scott R. Sayles, Mead, WA (US)

(21) Appl. No.: 15/261,230

(22) Filed: Sep. 9, 2016

Related U.S. Application Data
(60) Provisional application No. 62/293,245, filed on Feb. 9, 2016.

(51) Int. Cl. H01J 37/34

(52) U.S. Cl. CPC H01J 37/3423; H01J 37/3491

(57) ABSTRACT

A sputtering target assembly for use in a vapor deposition apparatus, the sputtering target assembly comprising a sputtering surface; a sidewall extending from the sputtering surface at an angle to the sputtering surface; a particle trap formed of a roughness located along the sidewall and extending radially from the sputtering surface, wherein the roughness of the particle trap has a macrostructure and a microstructure.

### CROSS-REFERENCE TO RELATED APPLICATIONS

This application claims priority to U.S. Provisional Patent Application Ser. No. 62/293,245, filed Feb. 9, 2016, the disclosure of which is expressly incorporated herein by reference in its entirety.

### TECHNICAL FIELD

The instant disclosure relates to particle traps for use in sputtering chambers and methods of doing the same. More particularly, the instant disclosure relates to particular aspects of forming roughened surfaces on chamber components exposed to deposition conditions. The roughened surfaces can be formed on, for example, a surface surrounding a sputtering surface on a sputtering target or a sputtering target assembly.

### BACKGROUND

Deposition methods are used for forming films of material across substrate surfaces. Deposition methods can be used in, for example, semiconductor fabrication processes to form metallized layers in the fabrication of integrated circuitry structures and devices. An exemplary deposition method that the instant application is applicable to is physical vapor deposition (“PVD”).

PVD methodologies, as an example, include sputtering processes. PVD sputtering methodologies are used extensively for forming thin films of material over a variety of substrates. A diagrammatic view of a portion of an exemplary physical vapor deposition apparatus 8 is shown in FIG. 1. In one configuration, a sputtering target assembly 10 comprises a backing plate 12 having a target 14 bonded thereto. A substrate 18 such as a semiconductive material wafer is within the PVD apparatus 8 and provided to be spaced from the target 14. A surface 16 of target 14 is a sputtering surface or sputtering face. As shown, the target 14 is disposed above the substrate 18 and is positioned such that surface 16 faces substrate 18. In operation, sputtered material 22 is displaced from the surface 16 of target 14 and used to form a coating or thin film 20 over substrate 18. In some embodiments, suitable substrates 18 include wafers used in semiconductor fabrication.

In an exemplary PVD process, the target 14 is bombarded with energy until atoms from the surface 16 are released into the surrounding atmosphere and subsequently deposited on substrate 18. In one exemplary use, plasma sputtering is used to deposit a thin metal film onto chips or wafers for use in electronics.

The target 14 may be formed from any metal suitable for PVD deposition processes. For example, the target 14 may include aluminum, vanadium, niobium, copper, titanium, tantalum, tungsten, ruthenium, germanium, selenium, zirconium, molybdenum, hafnium, and alloys and combinations thereof. When such exemplary metals or alloys are intended to be deposited as a film onto a surface, a target 14 is formed from the desired metal or alloy, from which metal atoms will be removed during PVD and deposited onto the substrate 18.

Problems can occur in deposition processes if particles are formed, in that the particles can fall into or onto a deposited film and disrupt desired properties of the thin film. Accordingly, it is desired to develop a sputtering target in which a reduced number of particles fall onto the deposited material during the deposition process.

### SUMMARY

Also described herein is a sputtering target assembly for use in a vapor deposition apparatus. The sputtering target assembly has a sputtering surface; a sidewall extending from the sputtering surface at an angle to the sputtering surface; and a particle trap formed of a roughness located along the sidewall and extending radially from the sputtering surface. The sputtering target assembly has a carbon atomic concentration of less than 40 percent at a depth less than 80 angstroms.

Also described herein is a target assembly for physical vapor deposition processes. The target assembly has a sputtering surface in a first plane; an outer flange in a second plane; a transition zone surrounding the sputtering surface and connecting the sputtering surface to the outer flange; and a particle trap located on the transition zone. The particle trap has a surface roughness having a macrostructure and a microstructure.

Also described herein is a method of forming a particle trap on a sputtering target. The method comprises forming a sputtering surface in a first plane; forming a surface roughness on a surface surrounding the sputtering surface; mechanically abrading the surface roughness to form a macrostructure; and cleaning the sputtering target using at least one of plasma etching and chemical etching.

Also defined herein is a method of forming a particle trap on a sputtering target. The method comprises forming a sputtering surface in a first plane; forming a macrostructure on a surface surrounding the sputtering surface, with the macrostructure defining a first roughness. The method further comprises mechanically abrading the macrostructure to form a microstructure, the microstructure defining a second roughness; and further abrading the sputtering target using at least one of plasma etching and chemical etching. After the abrading, the macrostructure has a final height that is at least 50 percent the initial height of the macrostructure.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 is a schematic view of a portion of a physical vapor deposition apparatus.

FIG. 2 is a schematic view of a sputtering target as viewed from the top.

FIG. 3 is a cross sectional side view of a side of a sputtering target.

FIG. 4 is a cross sectional view of a surface of a target before a particle trap is created.

FIG. 5 is a cross sectional view of a side surface of a sputtering target with a surface roughness.

FIG. 6 is a cross sectional view of a side surface of a sputtering target with a surface roughness.

FIG. 7 is a close-up view of a particle trap roughness.

FIG. 8 is an exemplary flow diagram of a method of forming a sputtering target having a particle trap.

FIG. 9 is an overall image of a particle trap showing certain characteristics.

FIG. 10 is an image of a particle trap showing certain characteristics.

FIG. 11 is an image of a particle trap showing certain characteristics.

FIG. 12 is an image of a particle trap showing certain characteristics.

FIGS. 13A, 13B, and 13C are images of a particle trap that has been machine roughened at three increasing orders of magnification.

FIGS. 14A, 14B, and 14C are images of a particle trap that has been machine roughened and bead-blasted at three increasing orders of magnification.

FIGS. 15A, 15B, and 15C are images of a particle trap that has been machine roughened, bead-blasted and chemically abraded at three increasing orders of magnification.

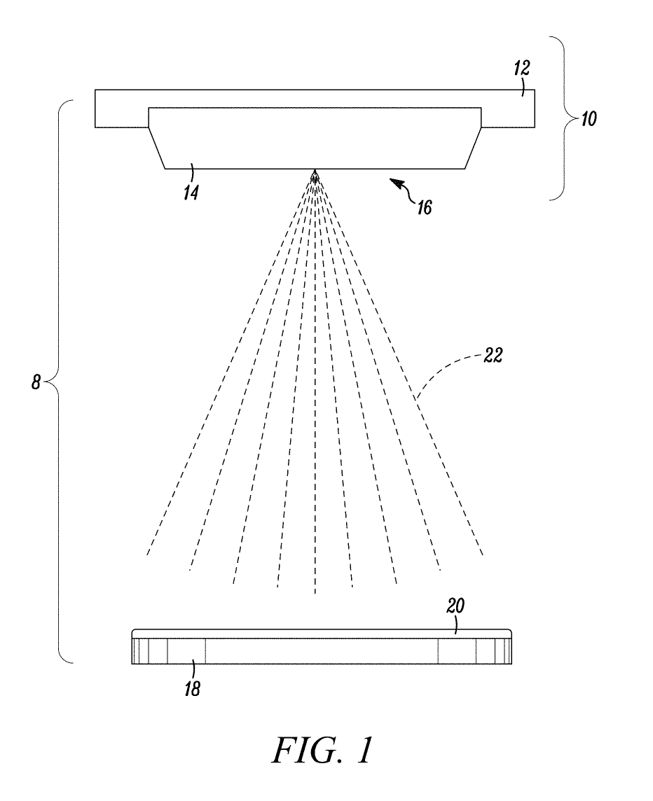

### DETAILED DESCRIPTION

The instant disclosure relates to methods of forming traps for particle entrapment in deposition chambers and in certain aspects pertains to methods of forming roughened surfaces on chamber components exposed to deposition conditions. In general, a portion of the surface or surfaces may be overall roughened or machined textured to form a macrostructure having roughness on the surface of the sputtering target components. Select portions of the surface may be roughened, in particular a portion of a sputtering target that forms the particle trap of the target may have roughness formed, followed by roughening by bead blasting using glass, metal, carbide, or oxide powders. The sputtering target may be chemically treated or plasma cleaned. The surface roughened area for the particle trap can be formed on, for example, one location or more of a target, for example on the surface, a bevel, a flange, an overhang, a slope, an undercut, a radius, or an edge, or any of a PVD chamber component. In some embodiments, the methods of the instant application may be applied to a sputtering target made from any of aluminum, tantalum, cobalt, copper, magnesium, nickel, tungsten, and alloys such as CuMn, WTi, NiPt, FeCoB, MgO, GeSbTe, GaAsTe, Si—GaAsTe, or C—GeSbTe.

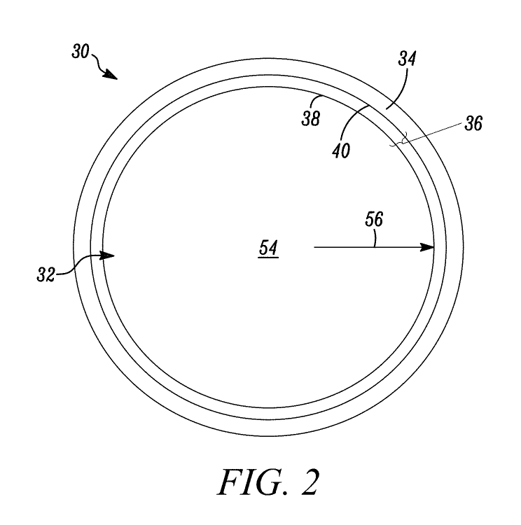

FIG. 2 shows a sputtering target 30 in an overall configuration. As shown in FIG. 2, in a top view, a sputtering target 30 typically has a sputtering surface 32, and a flange 34. In some embodiments, the sputtering target 30 is generally round or circular in a first plane around a central axis 54. The sputtering surface 32 is also circular with a first radius 56 as measured radially outward from the central axis 54 of the sputtering target 30. In some embodiments, the sputtering surface 32 may be generally planar in a first plane extending from the central axis 54 and extending outward in the radial direction. In some embodiments, the sputtering surface 32 is not planar and may have a convex or concave surface in the radial direction outward from the central axis 54.

The flange 34 may be generally flat or planar, for example, the flange 34 may be in a second plane that is relatively parallel to the sputtering surface 32 first plane. The flange 34 may be in a plane that is parallel to the first plane of the sputtering surface 32 but separated from the first plane by a distance in a direction along the central axis 54. In some embodiments, the flange 34 may be in a plane at an angle to the first plane of the sputtering surface 32. The sputtering surface 32 is held in place within a sputtering chamber by the flange 34. The sputtering surface 32 is thus attached to the flange 34, and the flange 34 is bolted or clamped to additional components of the sputtering apparatus for use.

In some embodiments, between the flange 34 and the sputtering surface 32 is an intermediate zone having, for example, a slope 36 and a sidewall 40. Where the slope 36 and the sputtering surface 32 meet, is a first transition point 38. In some embodiments, the intermediate zone may have a sidewall 40 and no slope 36. In some embodiments, the slope 36 may extend radially outward from the central axis 54 farther than the sputtering surface 32 and have a second radius. In some embodiments, the sidewall 40 may be attached to the slope 36.

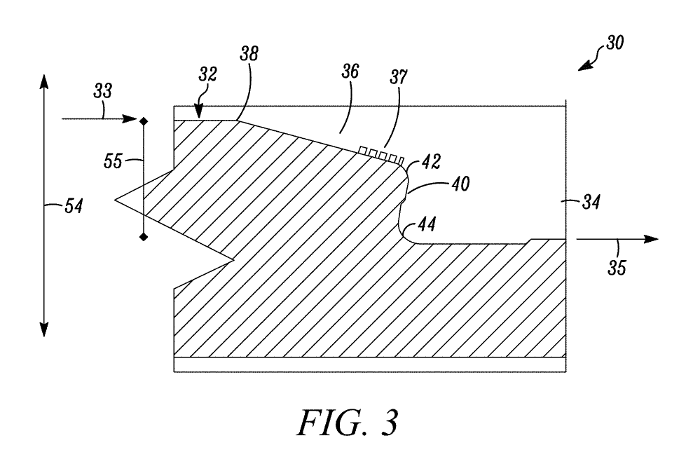

As shown in a side view of a portion of a sputtering target 30 in FIG. 3, in some embodiments, the edge of the sputtering surface 32 is relatively planar in a first plane, shown by arrow 33. The flange 34 may also be relatively planar and be in a second plane, shown by arrow 35, parallel to the first plane but separated a distance 55 as measured in a direction parallel to the central axis, the direction of which is shown in FIG. 3 by arrow 54.

Along the sputtering surface 32 outer radius is the first transition point 38 also in the first plane. The first transition point 38 marks the location where the sputtering surface 32 meets the slope 36. The slope 36 extends radially outward from the central axis shown by arrow 54 and ends at the sidewall 40. In some embodiments, the sidewall 40 and the slope 36 meet at a second transition point 42. In some embodiments, the sputtering target 30 does not have a slope 36 and the sputtering surface 32 is connected to the sidewall 40 at the first transition point 38. As illustrated in FIG. 3, the slope 36 is connected to the flange 34 with the sidewall 40. Where the sidewall 40 meets the flange 34 there may be a third transition point 44.

In some embodiments, the sidewall 40 may be substantially perpendicular to the sputtering surface 32. That is that the second transition point 42 may be the same radial distance from the central axis 54 as the third transition point 44. Alternatively, the sidewall 40 may be at an angle to the sputtering surface 32. For example, as shown in FIG. 3, the second transition point 42 may be located further from the central axis 54 in the radial direction than the third transition point 44. In some embodiments, the sidewall 40 may also include additional features such as an overhang near the second transition point 42 or an undercut near the third transition point 44. In some embodiments, the second transition point 42 may be located closer to the central axis 54 than the third transition point 44.

In some embodiments, a particle trap is formed on a portion of the sputtering target 30 around the sputtering surface 32, for example, along the slope 36 or along the sidewall 40. As shown in FIG. 3, a particle trap may be located along an outer diameter 37 around the sputtering surface 32. The particle trap may be located on portions of the target surface 32 near the outer diameter 37. In some embodiments, a particle trap is formed on a portion of the flange 34. The particle trap may also be located both on a portion of the sidewall 40 and a portion of the flange 34. For example, a particle trap may be located on a portion of the sidewall 40, extend along the third transition point 44, and extend over a portion of the flange 34.

The flange 34 may also have sloped portions in an outward radial direction from the central axis 54. For example, the flange 34 may have portions that are located a distance along the central axis 54 further away from the third transition point 44. In some embodiments, the flange 34 may include additional features such as O-ring grooves formed into the flange 34. The flange 34 may have additional stepped portions even further away from the third transition point 44 along the direction of the central axis 54.

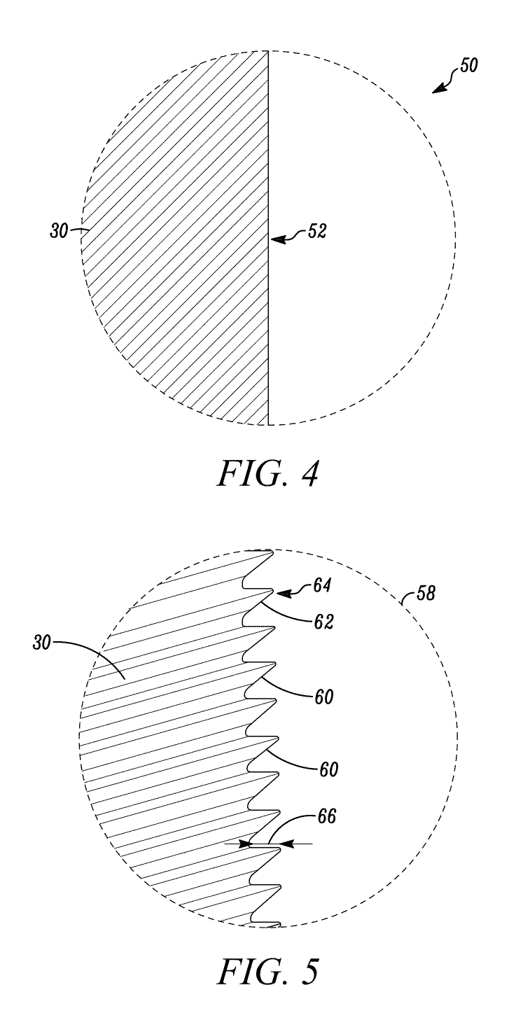

FIG. 4 shows an expanded view of a portion of a surface 50 of the sputtering target 30 of FIGS. 2 and 3 at a preliminary processing stage or before a surface roughness has been formed. As shown in FIG. 4, a portion of the surface 50 has a relatively planar or flat surface 52 that may be at an angle to the sputtering surface. The planar or flat surface 52 may be how a portion of the sputtering target appears before a machining step. The planar or flat surface 52 may be any surface along the sidewall 40 and/or flange 34 of FIGS. 2 and 3.

As shown schematically in FIG. 5, a surface roughness may be added to the relatively flat or planar surface 52 of FIG. 4. FIG. 5 illustrates an expanded view of a portion 58 of a surface of the sputtering target 30 of FIGS. 2 and 3 after it has been treated to form a roughness 60 extending across a surface of the sputtering target 30. The roughness 60 may be formed along the sidewall 40 and/or flange 34 of a sputtering target 30 as shown in FIG. 3. The roughness 60 can be formed using a saw, knurling device, computer numerically controlled (CNC) device, manual lathe or other suitable machining tool, and can correspond to a random or repeating pattern. A saw can be used to cut into a surface such as the surface of the material forming the sidewall 40 and leave the pattern as shown. Alternatively or additionally, a knurling device can be used to press into the surface of the material and leave the desired pattern.

As shown in FIG. 5, in some embodiments the roughness 60 can have a particular shape when viewed from a cross-sectional view. In the example shown in FIG. 5, the roughness 60 may be in the form of projections have a wide base 62 at the location closest to and connected to the surface of the sputtering target 30. The roughness 60 may include narrow or pointed apexes 64 contributing to the surface area of the roughness 60. The roughness thus increases the surface area of the sputtering target 30. In various embodiments, a cross-sectional shape of the roughness 60 may be a wave pattern, a triangle pattern, a block pattern, a circular pattern or a random pattern.

In some embodiments, the roughness 60 has a height 66 above the surface of the sputtering target 30 of, for example, from about 550 to about 1150 micro-inches, from about 750 to about 1125 micro-inches, or from about 900 to about 1100 micro-inches. In some embodiments, the roughness 60 has a height 66 above the surface of the sputtering target 30 of, for example, from about 500 to about 700 micro-inches, from about 525 to about 675 micro-inches, or from about 550 to about 650 micro-inches. In some embodiments, the roughness 60 has a height 66 above the surface of the sputtering target 30 of, for example, from about 950 to about 1150 micro-inches, from about 975 to about 1125 micro-inches, or from about 1000 to about 1100 micro-inches.

In some embodiments, the roughness 60 may have a first overall shape. This first overall shape may also be referred to as a macrostructure. The macrostructure can also be subjected to further processing steps to change the shape or surface of the roughness 60. Additional surface texture may be added to the roughness. The additional surface texture that is added to the macrostructure may be referred to as a microstructure.

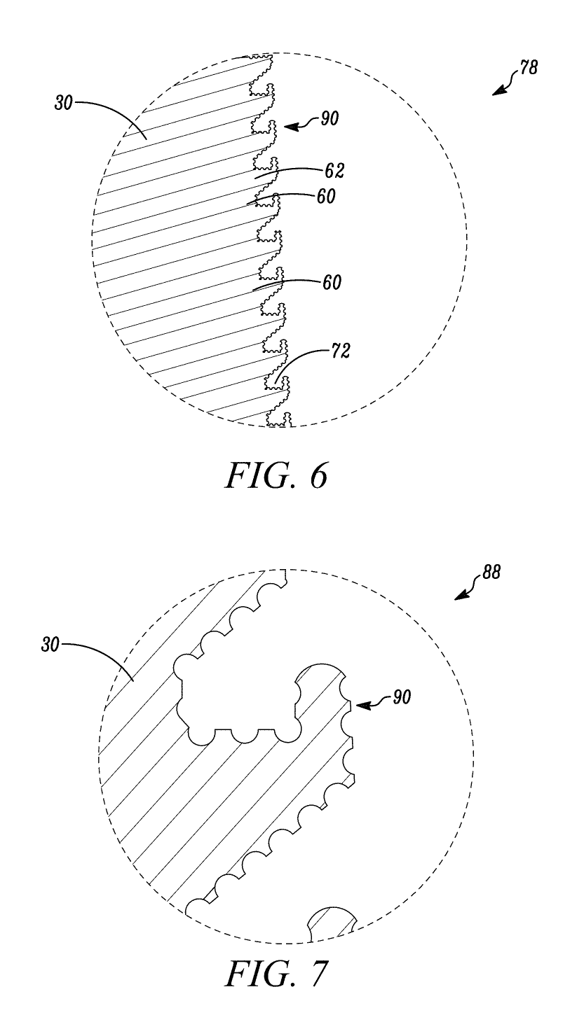

FIG. 6 illustrates an expanded view of a portion 78 of a surface of the sputtering target 30 of FIGS. 2 and 3, as in FIG. 5 after the roughness 60, also referred to herein as the macrostructure, has been subjected to additional processing. The roughness 60 illustrated in FIG. 5 can form suitable particle traps by creating an overall surface profile, and can be used in a sputtering chamber as is. The roughness 60 may be in the form of a repeating pattern, such as projections having a wide base 62 at the location closest to and connected to the surface of the sputtering target 30, and a gap 72 in between each of the projections that form the roughness 60. However, further processing to form an additional surface texture or microstructure 90 on the roughness 60, can enhance the particle-trapping capabilities of the roughness 60. In some embodiments, the roughness 60 may be subjected to mechanical abrasion to enhance the surface texture of the roughness 60. For example, a mechanical abrasion step may be used to add an additional surface texture to the sputtering target, for example along a flange, slope, sidewall, or undercut. A mechanical abrasion step can include bead blasting, wire brushing, filing, shot pining, or other methods of surface abrading. Although FIGS. 6 and 7 shows the roughness 60 as having a bent tip shape, in some embodiments the tips of the roughness 60 are not bent.

In some embodiments, after bead blasting, the roughness 60 can have an additional surface texture above the surface of the sputtering target 30 of, for example, from about 250 to about 1100 micro-inches. In some embodiments, after bead blasting the roughness 60 can have a height above the surface of the sputtering target 30 of, for example, from about 900 to about 1100 micro-inches, from about 925 to about 1075 micro-inches, or from about 930 to about 1040 micro-inches. In some embodiments, after bead blasting the roughness can have a height above the surface of the sputtering target 30 of, for example, from about 250 to about 450 micro-inches, and from about 200 to about 400 micro-inches.

Following the creation of the macrotexture and microtexture, the sputtering target 30 may be subjected to additional surface treatment, such as cleaning. For example, the sputtering target 30 may be subjected to plasma cleaning, or plasma etching to remove any residual material following the bead blasting. In another example, the sputtering target 30 may undergo a chemical etching or chemical cleaning step to remove any residual material or contamination following the sputtering target production and roughening steps. The sputtering target 3 may be exposed to nitric acid, hydrofluoric acid, or a combination of acids to carry out a chemical etching or cleaning. A cleaning step may be used to remove any residual contamination from the surface of the sputtering target 3, such as any bead blasting media.

In some embodiments, the chemical etching, chemical cleaning, plasma etching, or plasma cleaning may further enhance the surface texture or surface roughness of a particle trap located on the sputtering target 30 following a bead blasting step. FIG. 7 is a schematic view of a surface roughness 88 after it has been subjected to a chemical etching step that adds to the microstructure 90 extending from the surfaces of the macrostructure as texture or divots. In some embodiments, the surface treatment may be tailored to achieve a specified surface roughness 88. In some embodiments, after a chemical etching step the roughness may have a height above the surface of the sputtering target 30 of from about 300 to about 900 micro-inches. In some embodiments, after a chemical etching step the roughness may have a height above the surface of the sputtering target 30 from about 700 to about 1000 micro-inches, from about 750 to about 950 micro-inches, or from about 800 to about 900 micro-inches. In some embodiments, after a chemical etching step the roughness may have a height above the surface of the sputtering target 30 of from about 250 to about 500 micro-inches, or from about 300 to about 450 micro-inches. In some embodiments, the roughness may have a minimum of 32 micro-inches Ra.

The chemical etching or cleaning or plasma etching or cleaning provides additional surface cleanliness control as evidence by X-ray photon spectroscopy analyzed data showing significant reduction in the carbon content on the surface of the sputtering target 30. The chemical etching or cleaning or plasma etching or cleaning also provides additional micro-roughness control as measured by a laser non-contact roughness measured locally along both the sputtering surface and the particle trap area.

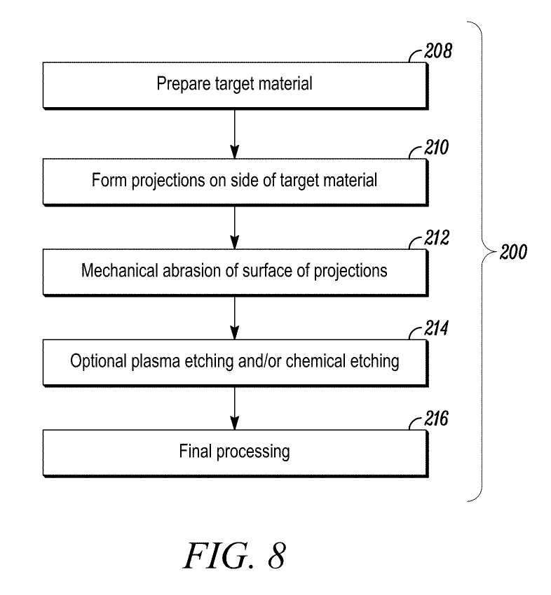

As shown in FIG. 8, a flow diagram of certain processing elements may be used in combination to carry out the method 200 of the instant disclosure. In some embodiments, a sputtering target can undergo a preparation step 208, by for example cleaning the target material for example to remove surface contaminants and prepare the target material for the process. In step 210, machining may be used to form a roughness on a particle trap portion of the sputtering target. The roughness may have a macrostructure forming cavities or receptacles. In step 212, the roughness may be subjected to a mechanical abrasion step such as a bead blasting process. Bead blasting may be carried out by subjecting the roughness to high velocity particles of silicon carbide, glass, alumina or silica to form a surface texture or microstructure. After mechanical abrasion, in step 214, the sputtering target may undergo an additional abrasion step for example chemical etching, abrading, cleaning or may undergo plasma etching, abrading or cleaning. As a final processing step 216, the sputtering target may undergo additional processing for example to remove any residual chemicals from the chemical or plasma etching, abrading, or cleaning.

When used in a sputtering process, sputtering targets having particle traps created using the methods described herein have been discovered to form deposition coatings with improved performance. It has been found that by abrading, etching, or cleaning the surface of the particle trap to remove contamination, the particle trap is able to retain sputtering material better during a sputtering process and thus produces a sputtered film having fewer contaminants.

One method of determining the improved performance is by measuring the number of particles or contaminants that end up in the sputtered surface after a sputtering process. Another measure of predicting a particle trap's performance is by measuring the amount of carbon contamination on the surface of the particle trap. A lowered carbon atomic concentration on the surface of the sputtering target and/or particle trap provides a sputtering target with enhanced processing performance during a sputtering process. It has been discovered, that using a chemical treatment or plasma treatment process following a bead blasting treatment produces a sputtering target having a lower level of carbon concentration as compared to a standard baseline sputtering target. For example, the carbon atomic concentration may be less than 45 percent, less than 30 percent, or less than 25 percent. These results indicate that the chemical treatment or plasma treatment step described herein contribute to creating a sputtering target with reduced carbon concentration or lower organic compounds or metallic trace elements in the sputtering target material, and in turn produces deposition products having fewer undesired particles. Thus the methods of the instant disclosure are suitable for creating a sputtering target having a particle trap containing a roughness Ra having a macrostructure, a microstructure, and lowered carbon content.

Chemicals used for an etching, abrading or cleaning step may be chosen based on the material the sputtering target is made from. For example, a diluted HF/HNO₃ solution may be used for a Ti or Ti alloy sputtering target. As another example, diluted HN₃ or diluted HCl may be used for a Cu or Cu alloy sputtering target such as a CuMn alloy. A diluted HF and/or HNO₃ solution may be suitable for a Ta target. A diluted HNO₃ solution may be used for Co or Co alloy targets. A diluted HF and/or HNO₃ solution may be used for an Al or an Al alloy target. Diluted HF and HNO₃ can also be used for steel or stainless steel targets. A diluted HF and/or HNO₃ solution may be used for a W sputtering target.

It has also been observed that sputtering targets that have been etched, abraded, or cleaned using the methods described herein have lower amounts of carbon contamination on the sputtering surface even after being bagged. Typically a sputtering target is placed in a packaging or bag after being produced, to protect the sputtering target during transit. The packaging or bag material is typically a polymer bag made from polymers such as polyethylene, PET, or other hydrocarbons. When the bag material is in contact with the sputtering target, the bag may rub against the sputtering target which causes trace levels of carbon to transfer to the sputtering surface. This trace carbon may contribute to contamination of the sputtered surface after a sputtering process. Using the etching, abrading, or cleaning methods described herein, a sputtering target having lower levels of carbon contamination has been made, and can be used to produce a sputtered surface having lower levels of particles even after the sputtering target has been subjected to a bagging step.

### EXAMPLES

The following non-limiting examples illustrate various features and characteristics of the present invention, which is not to be construed as limited thereto.

### Examples 1 and 2

In two examples, titanium sputtering target assemblies having particle trapping features surrounding a sputtering surface were formed. In a first step, the sputtering targets were subjected to a CNC lathe that formed a surface roughness with a macrostructure on the surface of the side of the sputtering target, to form a particle trap. The height of the macrostructure above the surface of the side of the sputtering target after the CNC lathe was applied is shown Table 1 below. The macrostructure was then subjected to a bead blasting step to add a microstructure to the macrostructure. The overall height of the roughness including the macrostructure and the microstructure after the bead blasting step is shown below in Table 1. Finally, the sputtering target was treated with a diluted HF/HNO₃ solution for the final chemical treatment step. Multiple samples with varying roughness values were prepared for each example. Tables 1 and 2 contain the values of the height of surface roughness above the surface of the side of the sputtering target after each step for each sample.

TABLE 1
Particle trap Experimental Value of Example 1

| | Roughness (Ra) (micro-inches) | | |
|---|---|---|---|
| | Sample 1 | Sample 2 | Sample 3 |
| After CNC Lathe | 1101 | 1089 | 1066 |
| After Bead Blast | 935 | 1032 | 933 |
| After HF/HNO₃ | 805 | 893 | 824 |

TABLE 2
Particle trap Experimental Value of Example 2

| | Roughness (Ra) (micro-inches) | | | | |
|---|---|---|---|---|---|
| | Sample | | Sample | | |
| Process | 1 | Sample 2 | 3 | Sample 4 | Sample 5 |
| After CNC Lathe | 563 | 593 | N/A | N/A | N/A |
| After Bead Blast | 334 | 398 | N/A | N/A | N/A |
| After HF/HNO₃ | 341 | 300 | 403 | 417 | 441 |

A chemical treatment step such as chemical abrasion may be used to tailor the surface roughness of a sputtering target and create a particle trap having certain desired properties. For example, a target surface having a particular surface roughness or height may be tailored by controlling the duration and type of chemical treatment used. If a particular surface roughness is desired, an initial roughness may be created using a bead blasting step. The initial roughness may be measured after the bead blasting step, and if the roughness is too high, a chemical treatment step such as chemical abrasion may be used to reduce the surface roughness to a more suitable height or texture. In this manner, a surface roughness or surface height may be created for use with a particular type of sputtering material, or a particular type of possible contaminant.

It has been found that performing a chemical treatment step following the bead blasting provides significant improvement. As shown in Table 3 below, a sputtering target which was treated with a chemical cleaning (Chemical Etch) or plasma cleaning (Plasma Etch) following the bead blasting process was shown to provide significantly lower levels of carbon concentration on the sputtering target compared to the control sputtering targets (STD Clean 1-4), when measured by X-ray photon spectroscopy (XPS).

XPS data is quantified using relative sensitivity factors and a model that assumes a homogeneous layer. The analysis volume is the product of the analysis area (spot size or aperture size) and the depth of penetration. Photoelectrons are generated within the X-ray penetration depth (typically many microns), but only the photoelectrons within the top three photoelectron escape depths are detected. Escape depths are on the order of 15-35 Å, which leads to an analysis depth of ˜50-100 Å. Typically, 95% of the signal originates from within this depth.

For the test method used to create the data in Table 3, the analytical parameters were as follows. The instrument used was a PHI Quantum 2000, available from Physical Electronics (located in Eden Prairie, Minn.). The X-ray source was a monochromated Alkₐ 1486.6 eV with an acceptance angle of ±23°, and a takeoff angle of 45°. The analysis area was 1400 mm×300 mm and the charge correction was Cls 284.8 eV.

As shown in Table 3, the carbon atomic concentration with improved treatment was less than half the amount that was found on control (STD Clean 1-4) sputtering targets. The carbon atomic concentration was measured at a depth of between 50 and 80 angstroms. The results also demonstrate improved adhesion of redeposited TiN/Ti film along the particle trapping surfaces.

TABLE 3
Carbon atomic concentration of the sputtering target surface.

| Clean Method | Carbon Atomic Concentration % |
|---|---|
| STD Clean 1 (control) | 54 |
| STD Clean 2 (control) | 45 |
| STD Clean 3 (control) | 45 |
| STD Clean 4 (control) | 51 |
| Chemical Etch | 20 |
| Plasma Etch | 21 |

### Example 3

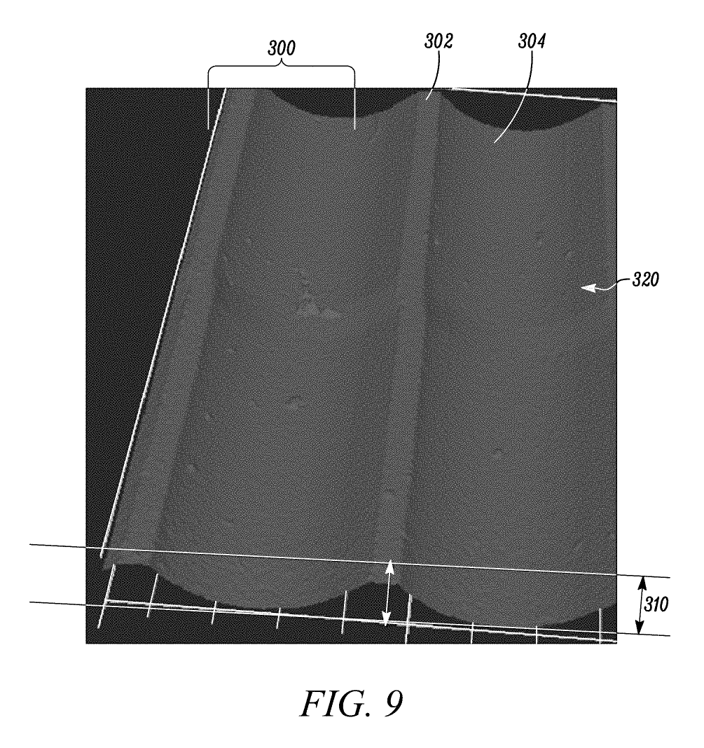

In a third example, the methods as disclosed above were carried out on a sample Ti target, and images are provided to show the locations of measurements and to illustrate certain characteristics. As shown in FIG. 9, a surface of a particle trap may contain a surface roughness that is characterized by a macrostructure 300, defined as an overall configuration of the surface. The macrostructure can be measured as having a height 310 also referred to as a profile above a surface. For example, the macrostructure may define valleys 304 or troughs at a depression, and peaks 302 or apexes at a projection. The height 310 of the macrostructure roughness Ra is measured from the bottom of a valley 304 to the top of a peak 302. Thus, a macrostructure 300 is measured over a large enough area of a surface to encompass at least one repeating unit of the macrostructure, such as over an area that includes both a valley 304 and a peak 302. As shown in FIG. 9, in areas smaller than the distance between one repeating unit of the macrostructure 300, such as between peaks 302 or within a valley 304, a localized area 320 of the surface may be relatively smooth.

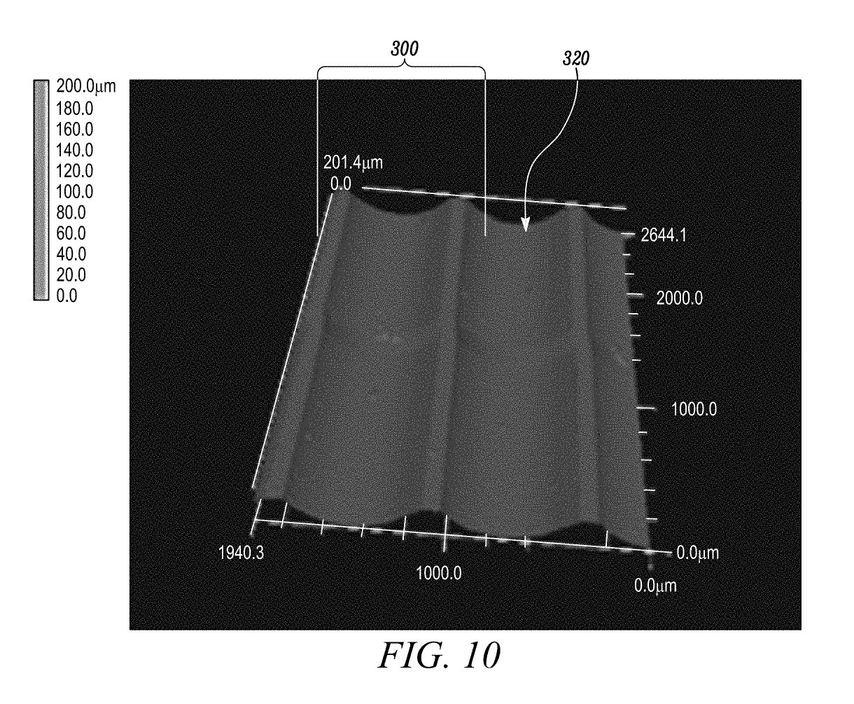

FIG. 10 shows a particle trap surface after being formed with a CNC lathe to illustrate the measurement scale and distances between certain features. The surface in FIG. 10 has a macrostructure 300 similar to that in FIG. 9. As shown in FIG. 10, in a localized area 320, such as on a scale smaller than one repeating unit of a macrostructure, the macrostructure 300 appears to be relatively smooth.

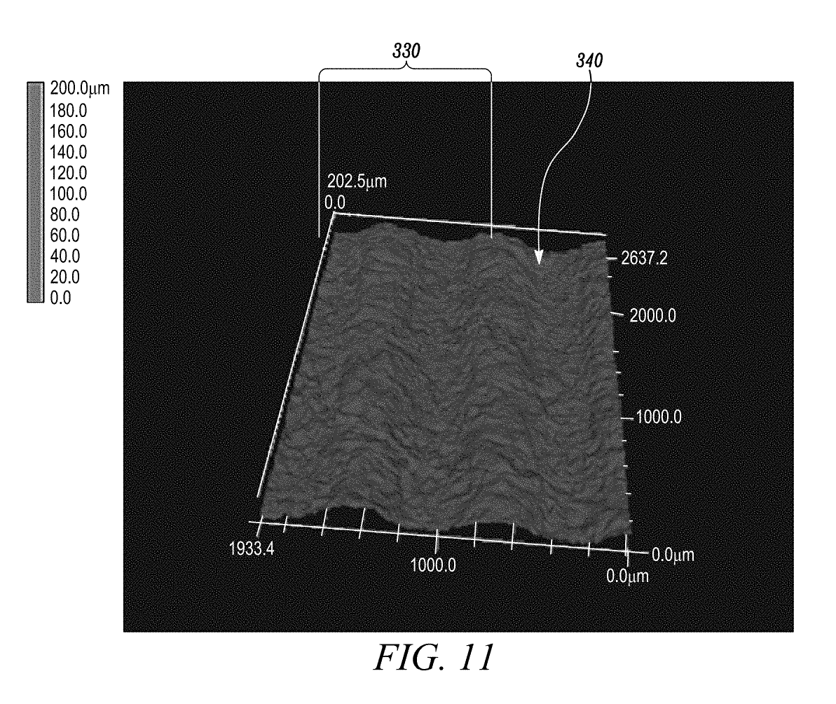

FIG. 11 shows the particle trap surface of FIG. 10 after it has been treated with bead blasting. The macrostructure 330 in FIG. 11 is the same macrostructure 300 described in FIGS. 9 and 10 after bead blasting. Comparing FIG. 11 to FIG. 10, it can be seen that the macrostructure 330 in FIG. 11 is worn or abraded and not as sharply defined as in the macrostructure 300 in FIG. 10. As shown in FIG. 11, after a mechanical abrasion step, a particle trap surface can also have a microstructure 340. The microstructure 340 is a localized texture that is found over the entire surface, including both the valleys 304 and the peaks 302 that were previously discussed with reference to FIG. 9. As shown in FIG. 11, the microstructure 340 forms an additional texture or roughness on the macrostructure 330. This additional texture increases the overall surface area of the particle trap, and increases the effectiveness of the particle trap because of the added texture or roughness.

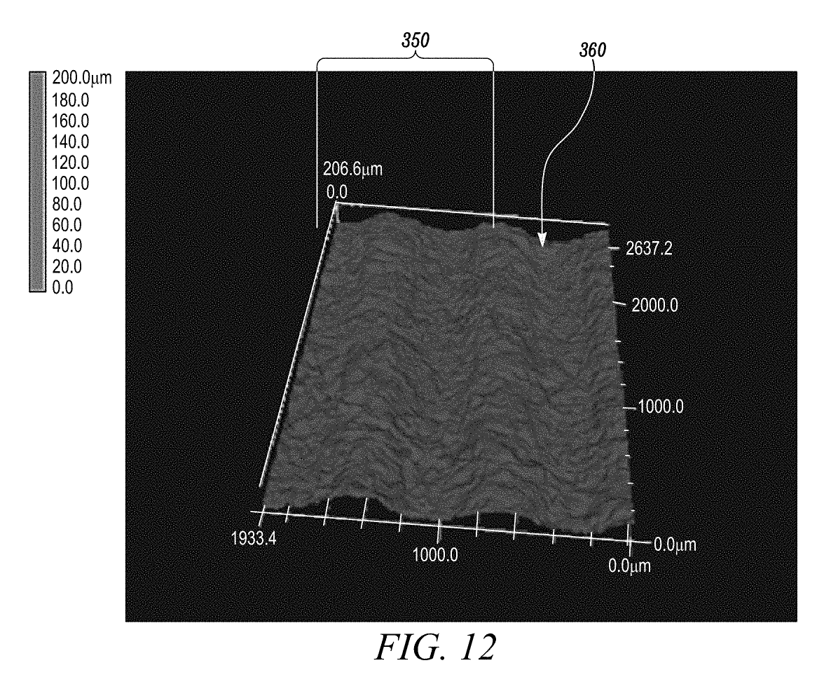

After a mechanical abrasion step, such as bead blasting, the particle trap may be subjected to chemical or plasma treatment. FIG. 12 shows the particle trap surface of FIG. 11 after it has been chemically treated with chemical abrasion. Comparing FIG. 12 to FIG. 11 and FIG. 10, it can be seen that the macrostructure 350 in FIG. 12 is abraded more than the macrostructure 330 in FIG. 11, resulting in a surface texture that has fewer sharp edges and is smoother than the macrostructure 300, 330 in either FIG. 10 or FIG. 11. The overall height of the macrostructure 350 above the surface of the sputtering target shown in FIG. 12 is less than the overall height of the macrostructure 300, 330 shown in FIG. 10 or FIG. 11. The microstructure 360 has a roughness Ra that is further abraded than the microstructure 340 of FIG. 11, and the overall height of the roughness including both the macrostructure and microstructure is less than the overall height of the roughness in FIG. 10 or 11.

Table 4 below contains measurements of the macrostructure Ra and microstructure Ra measured after each step used in creating the examples contained in FIGS. 9-12. As described above with reference to FIG. 9, the macrostructure Ra is measured from the bottom of the valleys 304 to the top of the peaks 302. The microstructure Ra is measured as the roughness above the macrostructure. As shown in Table 4, the macrostructure Ra is highest after the CNC lathe and the microstructure Ra is the lowest. After the bead blasting step, the macrostructure Ra has reduced and the microstructure Ra has increased. This is consistent with what would be expected after the peaks 302 or other features of the top of the macrostructure are abraded or worn down by the bead blasting. As shown in Table 4, comparing the microstructure roughness Ra before and after the bead blasting, the microstructure roughness Ra increased after the bead blasting. This is because the surface texture that forms the microstructure on the surface of the macrostructure was added by the bead blasting.

As shown in Table 4, after the bead blasting, the overall height of the macrostructure Ra was further reduced by the chemical abrasion. The overall height of the macrostructure Ra decreased and the microstructure roughness Ra increased after the chemical abrasion was applied to the bead blasted surface.

TABLE 4
Particle trap Surface Experimental Value of Example 3

| | Macrostructure Ra | Microstructure Ra |
|---|---|---|
| After CNC Lathe | 52.501 μm (2,066 μin) | 1.355 μm (53 μin) |
| After Bead Blasting | 41.295 μm (1,625 μin) | 6.410 μm (232 μin) |
| After Chemical Etch | 40.517 μm (1,595 μin) | 14.734 μm (580 μin) |

### Example 4

In a fourth example, a particle trap was formed on the side of a sputtering target using the methods disclosed above. The particle trap was photographed at varying magnifications using a scanning electron microscope available from FEITM (located in Hillsboro, Oreg.). The photographs of the particle trap were used to create FIGS. 13A-13C, 14A-14C, and 15A-15C.

FIG. 13A shows the surface of a sputtering target that has been surface treated by CNC lathe machining at a first magnification. The CNC lathe formed projections 380 which make up the macrostructure on the side of the sputtering target and creates the particle trap with a surface roughness. As shown in FIG. 13A, the projections 380 that form the macrostructure project from the surface of the sputtering target and form an overall surface profile with a first height. The projections appear from the scale of FIG. 13A to be about 1100 μm apart. The projections 380 form parallel lines to each other when viewed against the plane that the sputtering surface is in.

FIG. 13B shows the surface in between the projections 380 in FIG. 13A at greater magnification. As shown in FIG. 13B, the surface has a uniform or substantially smooth texture over a range of about 60.0 μm. Comparing the surface features between the two magnifications of FIG. 13A and 13B illustrates the range of the projections 380 that form the macrostructure and define the particle trap surface roughness. To view the projections 380 that form the macrostructure, a distance or range of about 1100 μm is needed. After only a CNC lathe step, within a distance or range of 60.0 μm, the surface appears to be relatively flat or smooth. FIG. 13C shows the same surface contained in FIGS. 13A and 13B at an even greater magnification. At a range or distance of about 9.00 μm, the microscopic features are viewable, and the surface appears almost flat in relation to the height of the macrostructure.

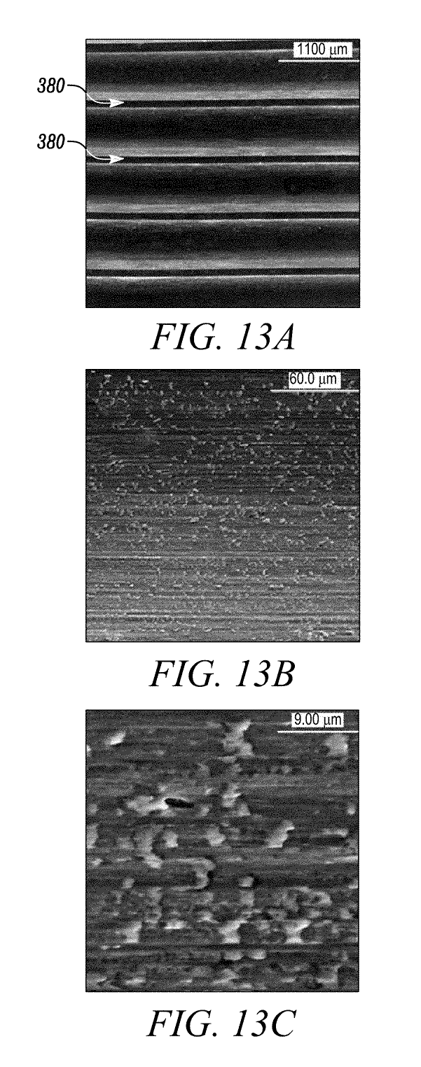

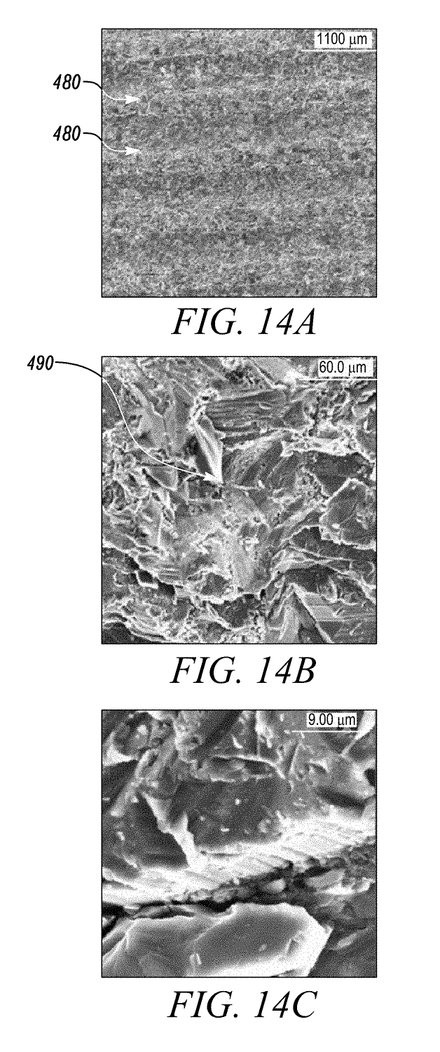

FIG. 14A shows the surface of FIG. 13A after it was treated with a bead blasting step at a first magnification. As shown in FIG. 14A, after bead blasting, the macrostructure 380 shown in FIG. 13A is changed when viewed over a distance or range of about 1100 μm. The projections 380 shown in FIG. 13A are abraded down, which reduced the overall height of the projections 380 from a first height shown in FIG. 13A to a second lower height shown in FIG. 14A. The macrostructure of FIG. 13A now has a microstructure added to it. Comparing the height of the projections 480 in FIG. 14A to the projections 380 in FIG. 13A the overall height has been reduced. FIG. 14B shows the same surface contained in FIG. 14A at greater magnification, and a microstructure is shown. As shown in FIG. 14B, after the bead blasting, although the surface has the same overall profile, rather than the smooth surface at a range of 60.0 μm as in FIG. 13B, the surface now has a texture or roughness over the same range. After the bead blasting step, the surface has edges that have sharp projections 490. FIG. 14C shows the same surface contained in FIGS. 14A and 14B at an even greater magnification. As shown in FIG. 14C, down to a range of 9.00 μm, the surface has a jagged rough texture with features that are sharper and more pronounced than the surface shown in FIG. 13C.

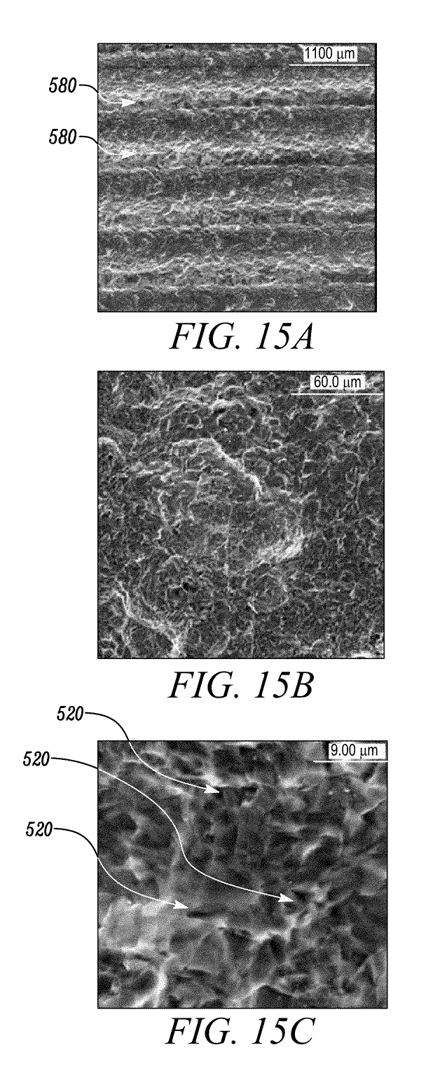

FIG. 15A shows the surface of FIG. 14A at a first magnification after a chemical abrasion has been applied. As shown in FIG. 15A, the overall height of the projections 480 in FIG. 14A are reduced even further, yet the projections 580 are still visible in FIG. 15A, showing that the projections 580 still define an overall height of the roughness above the surface of the sputtering target. Because the projections 480 are still visible, for example as parallel lines, is it apparent that the height of the projections 580 is still greater than the height of the microstructure above the macrostructure. That is, the height of the macrostructure from the surface of the sputtering target is still greater than the height of the microstructure from the surface of the sputtering target.

As shown in FIG. 15A, the overall surface texture is rounded or smoother than the surface texture of FIG. 14A, when viewed over a distance or range of about 1100 μm. FIG. 15B shows the same surface contained in FIG. 15A at greater magnification. Comparing FIG. 15B and FIG. 14B, the sharp projections 490 in FIG. 14B appear to be smoother and rounded at a range of about 60.0 μm. FIG. 15C shows the same surface contained in FIGS. 15A and 15B at an even greater magnification. As shown in FIG. 15C, over a distance or range of 9.00 μm, micro-voids 520 can be seen. These micro-voids 520 are created when the chemical abrasion treatment micro-roughens or etches the surface of the particle trap after the blead-blasting step. The micro-voids 520 are visible as cavities or craters that provide greater surface texture to the particle trap and can increase the effectiveness of the particle trap.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above described features.

What is claimed is:

1. A sputtering target assembly for use in a vapor deposition apparatus, the sputtering target assembly comprising:
a sputtering surface;
a sidewall formed on a second surface extending from the sputtering surface at an angle to the sputtering surface; and
a particle trap formed of a roughness on the second surface, the particle trap extending radially from the sputtering surface;
wherein the sputtering target assembly has a carbon atomic concentration of less than 40 percent at a depth less than 80 angstroms from the sputtering surface.

2. The sputtering target assembly of claim 1, wherein the particle trap includes a macrostructure and a microstructure.

3. The sputtering target assembly of claim 2, wherein the macrostructure defines a first surface roughness having a first height and the microstructure defines a second surface roughness having a second height, and wherein the second height is less than one half the first height.

4. The sputtering target assembly of claim 1, wherein the particle trap includes a macrostructure that includes projections formed by a CNC lathe and a microstructure that includes a surface texture formed on the projections by bead blasting.

5. The sputtering target assembly of claim 1, wherein the particle trap includes a macrostructure formed by a CNC lathe and a microstructure formed on the macrostructure by bead blasting and plasma etching.

6. The sputtering target assembly of claim 2, wherein the macrostructure comprises projections formed by a CNC lathe and the microstructure comprises a surface texture formed on the projections by bead blasting and chemical etching.

7. The sputtering target assembly of claim 1, wherein the particle trap comprises a bead blasted surface that has been subjected to chemical etching with at least one of nitric acid and hydrofluoric acid.

8. The sputtering target assembly of claim 2, wherein the microstructure includes micro-voids defined in a surface of the particle trap.

9. The sputtering target assembly of claim 1, wherein the particle trap has a surface roughness of from about 32 micro-inches to about 3000 micro-inches.

10. The sputtering target assembly of claim 1, wherein the particle trap has a surface roughness of from about 100 micro-inches to about 1200 micro-inches.

11. The sputtering target assembly of claim 1, wherein the particle trap has a surface roughness of from about 300 micro-inches to about 500 micro-inches.

12. A method of forming a particle trap on a sputtering target, the method comprising:
forming a sputtering surface in a first plane;
forming a macrostructure having an initial height on a surface surrounding the sputtering surface, the macrostructure defining a first roughness Ra;
mechanically abrading the macrostructure to form a microstructure, the microstructure defining a second roughness Ra; and
abrading the sputtering target using at least one of plasma etching and chemical etching, wherein after the abrading, the macrostructure has a final height that is at least 50 percent the initial height of the macrostructure.

13. The method of claim 12, further comprising forming an overhang between the sputtering surface and the surface surrounding the sputtering surface.

14. The method of claim 12, wherein the macrostructure and microstructure are formed on a surface that is at an angle to the first plane.

15. The method of claim 12, wherein the macrostructure has an initial height of from about 500 micro-inches to about 1200 micro-inches.

16. The method of claim 12, wherein after mechanically abrading, the macrostructure has a height of about 300 micro-inches to about 1100 micro-inches.

17. The method of claim 12, wherein after abrading, the macrostructure has a final height of from about 275 micro-inches to about 900 micro-inches.

18. The method of claim 12, wherein after abrading, the final height of the macrostructure is greater than twice a height of the second roughness Ra of the microstructure.

19. The method of claim 12, wherein the method provides a sputtering target assembly having a carbon atomic concentration of less than 40 percent as measured by X-ray photon spectroscopy.

20. The method of claim 12, wherein the method provides a sputtering target assembly having a carbon atomic concentration of less than 25 percent as measured by X-ray photon spectroscopy.
